(19) United States
(12) Patent Application Publication
(10) Pub. No.: US 2006/0186310 A1
(43) Pub. Date: Aug. 24, 2006

(54) Flat panel display device

(75) Inventor: Chi - Cheng Ho, Taipei (TW)

Correspondence Address: QUINTERO LAW OFFICE, 1617 BROADWAY, 3RD FLOOR, SANTA MONICA, CA, 90404, US

(73) Assignee: BENQ CORPORATION, TAOYUAN (TW)

(21) Appl. No.: 11/356,596

(22) Filed: Feb. 17, 2006

(30) Foreign Application Priority Data
Feb. 23, 2005 (TW) TW94105395

(51) Int. Cl. G06F 1/16; H05K 7/00

(52) U.S. Cl. 248/917; 361/681

(57) ABSTRACT

A flat panel display device. The flat panel display device comprises a base structure, a panel module, and a retaining structure. The base structure has a positioning hole, extending in a first direction and a second direction. The panel module comprises an engaging portion, inserted in the positioning hole such that the panel module is positioned in a predetermined position of the base structure. The engaging portion and the positioning hole prohibit the panel module from moving in the first direction. The retaining structure is disposed in the base structure. When the panel module is at the predetermined position, the retaining structure prevents the panel module from moving in the second direction.

### BACKGROUND

The invention relates to a flat panel display device, and in particular to connection of the panel of the flat panel display.

As display device technology improves, conventional cathode ray tube (CRT) display devices have been modified and various types of new display devices have been developed, such as flat panel display devices, liquid crystal displays (LCD) and plasma display devices. Flat panel display devices are light weight, have a thin profile, low power consumption, and high brightness. Thus, they are popular and frequently applied in consumer products such as communication and information electronic devices.

A panel is the main component in a flat panel display device. In an LCD, for example, an image is produced via a liquid crystal panel. Other flat panel display devices have different types of panel structures. In general, the panel is attached to a base structure of the flat panel display device by screws and other similar engagement methods. The number of screws required, however, is great. For example, at least four screws are required to securely attach the panel to the base structure for secure connection, which is time-consuming and expensive.

### SUMMARY

The invention provides a flat panel display device comprising a base structure, a panel module, and a retaining structure. The base structure has a positioning hole, extending in a first direction and a second direction. The panel module comprises an engaging portion, inserted in the positioning hole such that the panel module is positioned in a predetermined position of the base structure. The engaging portion and the positioning hole prohibit the panel module from moving in the first direction. The retaining structure is disposed in the base structure. When the panel module is at the predetermined position, the retaining structure prevents the panel module from moving in the second direction.

### BRIEF DESCRIPTION OF THE DRAWINGS

The invention can be more fully understood by reading the subsequent detailed description in conjunction with the examples and references made to the accompanying drawings, wherein:

FIG. 1 is an exploded view of an embodiment of a flat panel display device of the invention;

FIG. 2A is a local enlarged view of the engaging portion viewed in direction Y of FIG. 1;

FIG. 2B is a local enlarged view of the positioning hole viewed in direction Z of FIG. 1;

FIG. 3 is an exploded view of another embodiment of a flat panel display device of the invention;

FIG. 4A is a local enlarged view of the engaging portion viewed in direction Y of FIG. 3;

FIG. 4B is a local enlarged view of the positioning hole viewed in direction X of FIG. 3.

### DETAILED DESCRIPTION

The flat panel display device of the invention is described hereinafter by providing two embodiments as examples. During assembly, the elements are moved in three directions X, Y, and Z of an orthogonal coordinate system.

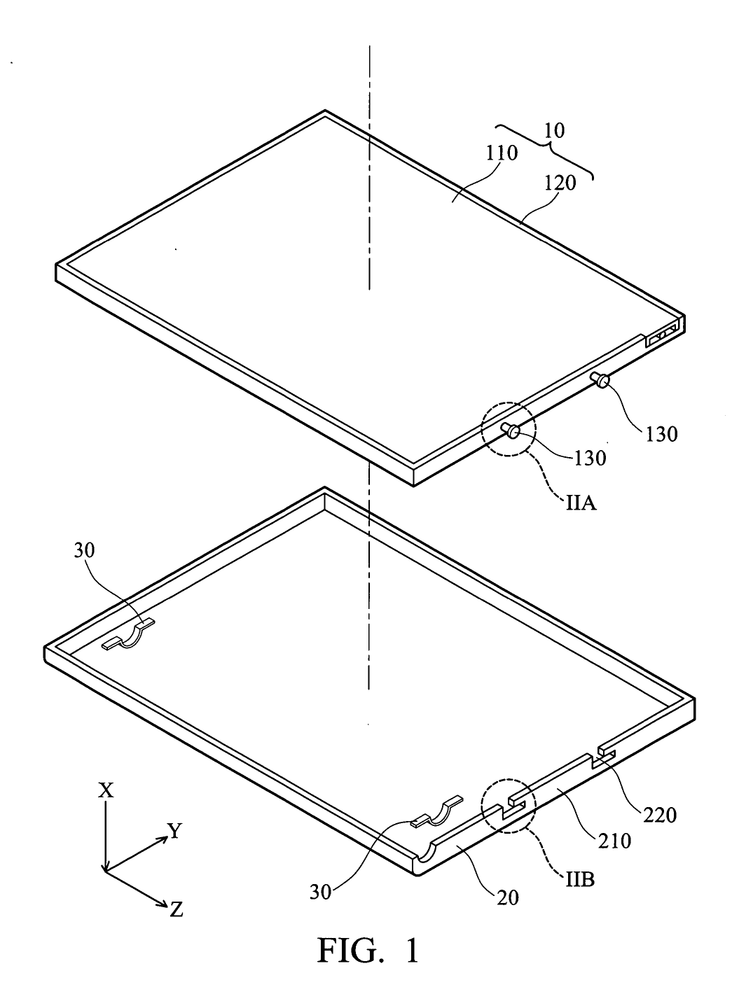

As shown in FIG. 1, the flat panel display device comprises a panel module 10, a base structure 20, and at least one retaining structure 30, and in this embodiment, two retaining structures. The following describes each element.

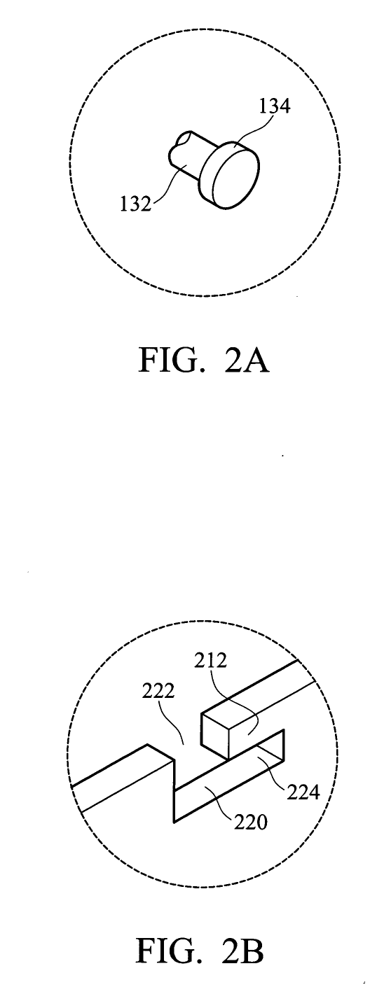

The panel module 10 comprises a display panel 110 and a frame 120 surrounding an exterior edge of the display panel 110. Two sides of the frame 120 are provided with at least one engaging portion 130. In FIG. 1, two engaging portions 130 are provided at each side, respectively. FIG. 2A shows the engaging portion 130. The engaging portion 130 has a cylindrical T-shape, comprising a first portion 132 and a second portion 134. The second portion 134 is larger than the first portion 132.

The base structure 20 is engaged with the panel module 10. The base structure 20 comprises engaging surfaces 210, each corresponding to a side of the frame 120 of the panel module 10 and opposing one another. Each engaging surface 210 comprises at least one positioning hole 220. In FIG. 1, there are two positioning holes 220. As shown in FIG. 2B, the positioning hole 220 is L-shaped, corresponding to the shape of the engaging portion 130. The positioning hole 220 comprises a third portion 222 and a fourth portion 224. The third portion 222 extends in direction X and outwardly with an open end. The fourth portion 224 extends in direction Y with a closed end. Namely, the positioning hole 220 substantially extends from the third portion 222 in direction X and changes to the fourth portion 224 in direction Y. Moreover, a first constraining portion 212 is formed on the engaging surface 210 in the vicinity of the fourth portion 224 of the positioning hole 220.

The retaining structure 30 is a flexible structure, shaped as a resilient plate, disposed in the base structure 20. The flexibility of the retaining structure 30 secures the connection between the panel module 10 and the base structure 20.

During assembly of the flat panel display device, the first portion 132 of the engaging portion 130 of the panel module 10 enters the third portion 222 of the positioning hole 220 in direction X, and is then engaged with the fourth portion 224 of the positioning hole 220 in direction Y. Thus, the engaging portion 130 is inserted in the positioning hole 220 such that the panel module 10 is located at a predetermined position of the base structure 20. The first constraining portion 212 around the positioning hole 220 and the first portion 132 of the engaging portion 130 restrict movement of the panel module 10 in direction X. The retaining structure 30 restricts the panel module 10 in direction Y. The second portion 134 of the engaging portion 130 and the engaging surface 210 restrict movement of the panel module 10 in direction Z. The panel module 10, thus, is securely engaged with the base structure 20 by the engaging portion 130 and the positioning hole 220.

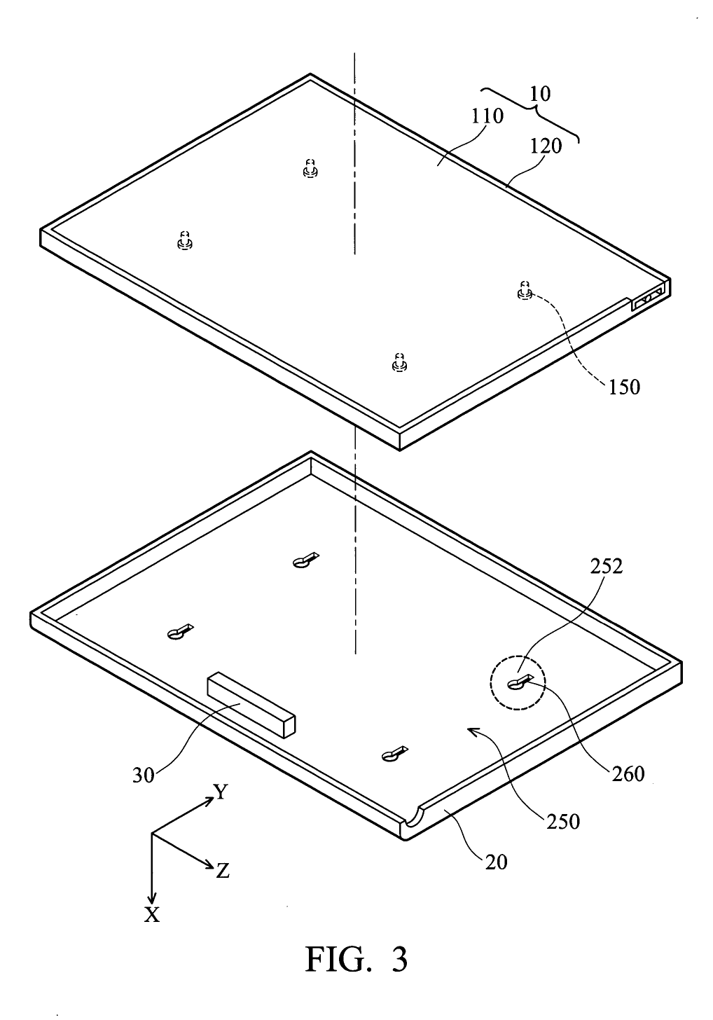

As shown in FIG. 3, another embodiment of the flat panel display comprises a panel module 10, a base structure 20, and a retaining structure 30.

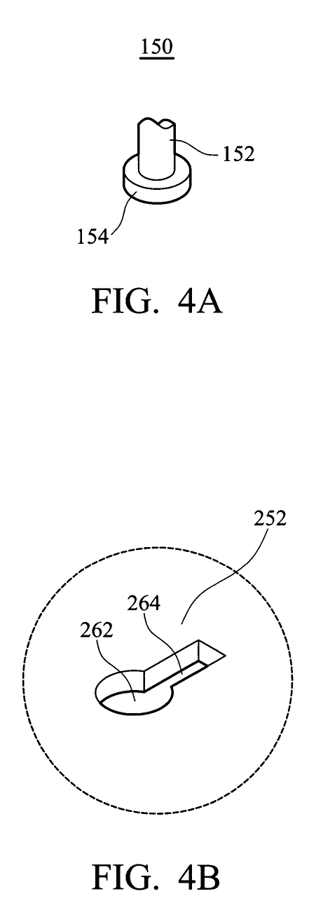

The panel module 10 comprises a display panel 110 and a frame 120, surrounding the exterior edge of the display panel 110. The frame 120 is provided with at least one engaging portion 150, extending in direction X. In FIG. 3, four engaging portions 150 are provided at each side of the frame 120, respectively. As shown in FIG. 4A, the engaging portion 150 is clearly shown. The engaging portion 150 has a cylindrical T-shape, comprising a first portion 152 and a second portion 154. The second portion 154 is larger than the first portion 152.

The base structure 20 is engaged with the panel module 10. The base structure 20 comprises a bottom surface 250 facing the direction of the panel module 10, with at least one positioning hole 260 defined thereon. FIG. 3 shows four positioning holes 260. The engaging portion 150 corresponds to the positioning hole 260. As shown in FIG. 4B, the positioning hole 260 comprises a third portion 262 and a fourth portion 264. The size of the third portion 262 is substantially the same as or slightly larger than the second portion 154 of the engaging portion 150. The fourth portion 264 extends from the third portion 262 in direction Y. The fourth portion 264 is smaller than the second portion 154 of the engaging portion 150, but substantially the same as or slightly larger than the first portion 152 of the engaging portion 150. Thus, the engaging portion 150 enters the third portion 262 of the positioning hole 260 in direction X, and is engaged with the fourth portion 264 of the positioning hole 260 in direction Y. Moreover, a second constraining portion 252 is formed on the bottom surface 250 in the vicinity of the fourth portion 264 of the positioning hole 260.

The retaining structure 30 is a flexible structure, shaped as a resilient plate, disposed in the base structure 20. The flexibility of the retaining structure 30 secures the connection between the panel module 10 and the base structure 20.

During assembly of the flat panel display device, the first portion 152 of the engaging portion 150 of the panel module 10 enters the third portion 262 of the positioning hole 260 in direction X, and is then engaged with the fourth portion 264 of the positioning hole 260 in direction Y. Thus, the engaging portion 150 is inserted in the positioning hole 260 such that the panel module 10 is located at a predetermined position of the base structure 20. The second constraining portion 252 around the positioning hole 260 and the first portion 152 of the engaging portion 150 restrict movement of the panel module 10 in direction X. The retaining structure 30 restricts the panel module 10 in direction Y. The second portion 154 of the engaging portion 150 and the bottom surface 250 restrict movement of the panel module 10 in direction Z. The panel module 10, thus, is securely engaged with the base structure 20 by the engaging portion 150 and the positioning hole 260.

The invention provides an easy and rapid method of combining the engaging portion 130 and the positioning hole 220 to provide secure connection between the panel module 10 and the base structure 20. Thus, the invention does not require screw during engagement, thereby saving assembly time.

In the described embodiments, the size, shape, number, and position of the elements described can be modified and rearranged at different locations, not limited to the figures and the description mentioned.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flat panel display device, comprising:
a base structure, having a positioning hole, extending in a first direction and a second direction;
a panel module, comprising an engaging portion, inserted in the positioning hole such that the panel module is positioned in a predetermined position of the base structure, both the engaging portion and the positioning hole preventing the panel module from moving in the first direction; and
a retaining structure, disposed in the base structure; when the panel module is at the predetermined position, the retaining structure prevents the panel module from moving in the second direction.

2. The flat panel display device as claimed in claim 1, wherein the engaging portion comprises a first portion and a second portion, wherein the second portion is larger than the first portion.

3. The flat panel display device as claimed in claim 2, wherein the base structure comprises an engaging surface with the positioning hole defined thereon, and the first portion of the engaging portion is engaged with the positioning hole in the first direction, and the second portion and the engaging surface prohibit the panel module from moving in a third direction.

4. The flat panel display device as claimed in claim 2, wherein the positioning hole comprises a third portion and a fourth portion, and the engaging portion enters the third portion of the positioning hole in the first direction and is engaged with the fourth portion of the positioning hole in the second direction.

5. The flat panel display device as claimed in claim 4, wherein a first constraining portion is formed on the engaging surface in the vicinity of the fourth portion of the positioning hole; when the panel module is at the predetermined position, the first constraining portion and the engaging portion restricts movement of the panel module in the first direction; the retaining structure restricts movement of the panel module in the second direction; and the second portion of the engaging portion and the engaging surface restrict movement of the panel module in the third direction.

6. The flat panel display device as claimed in claim 1, wherein the panel module further comprises a frame and a display panel; the frame surrounding the display panel, and the engaging portion is disposed on the frame.

7. The flat panel display device as claimed in claim 1, wherein the positioning hole is L-shaped, and the engaging portion is T-shaped, the positioning hole and the engaging portion are shaped according to each other.

8. The flat panel display device as claimed in claim 1, wherein the base structure comprises a bottom surface with the positioning hole defined thereon, and the engaging portion faces the positioning hole.

9. The flat panel display device as claimed in claim 8, wherein the engaging portion comprises a first portion and a second portion larger than the first portion.

10. The flat panel display device as claimed in claim 9, wherein the second portion of the engaging portion enters the positioning hole in the first direction, and the first portion is engaged with the positioning hole in the second direction.

11. The flat panel display device as claimed in claim 9, wherein the positioning hole comprises a third portion and a fourth portion; the engaging portion enters the third portion of the positioning hole in the first direction and is engaged with the fourth portion of the positioning hole in the second direction.

12. The flat panel display device as claimed in claim 11, wherein a second constraining portion is formed on the bottom surface in the vicinity of the fourth portion of the positioning hole; when the panel module is at the predetermined position, the second constraining portion and the engaging portion restrict movement of the panel module in the third direction; the retaining structure restricts movement of the panel module in the second direction; and the engaging portion and the bottom surface restrict movement of the panel module in the first direction.
